(19) United States
(12) Patent Application Publication
(10) Pub. No.: US 2007/0152558 A1
(43) Pub. Date: Jul. 5, 2007

(54) Organic thin film transistor array panel

(75) Inventors: Keun-Kyu Song, Yongin-si (KR); Yong-Uk Lee, Seongnam-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/639,202

(22) Filed: Dec. 13, 2006

(30) Foreign Application Priority Data
Dec. 14, 2005 (KR) 10-2005-0123385

(51) Int. Cl. H01J 1/02

(52) U.S. Cl. 313/309

(57) ABSTRACT

A thin film transistor array panel includes a substrate, a data line formed on the substrate, a source electrode connected to the data line, a drain electrode including a portion opposing the source electrode, a partition having an opening exposing portions of the source and drain electrodes, an organic semiconductor formed in the opening, a gate insulator formed on the organic semiconductor, and a gate line crossing the data line and having a gate electrode.

### CROSS-REFERENCE TO RELATED APPLICATION

This application claims priority to and the benefit of Korean Patent Application No. 10-2005-0123385 filed in the Korean Intellectual Property Office on Dec. 14, 2005, the contents of which are herein incorporated by reference.

### FIELD OF THE INVENTION

The present invention relates to an organic thin film transistor array panel and a manufacturing method thereof.

### DESCRIPTION OF THE RELATED ART

Generally, a flat panel display such as a liquid crystal display (LCD), an organic light emitting diode (OLED) display, and an electrophoretic display includes a pair of electric-field generating electrodes and an electro-optical active layer disposed between them. As the electro-optical active layer the LCD includes a liquid crystal layer while the OLED display includes an organic light emitting layer.

One of the pair of field generating electrodes is usually coupled with a switching element to receive electrical signals, and the electro-optical active layer converts the electrical signals into optical signals to display images. The display includes a plurality of three terminal thin film transistor (TFT) switching elements. Gate lines transmit control signals to the gate electrode while data lines transmit data signals to the source electrodes. Pixel electrodes are connected to the drain electrodes of the TFTs. Among the TFTs, organic thin film transistors (OTFT) employ an organic semiconductor instead of an inorganic semiconductor such as Si.

An OTFT manufactured using a low temperature solution process is more adapted to making large size flat panel displays than a deposition process. Also, because the OTFT uses organic material patterns made of a fiber or a film, the OTFT yields a flexible display device. However, the organic semiconductor material limits the kinds of manufacturing processes that can be employed.

### SUMMARY OF THE INVENTION

A motivation of the present invention is to provide an organic thin film transistor array panel and a manufacturing method that minimizes the influence of the organic semiconductor material on the manufacturing process and that simplifies the manufacturing process.

A thin film transistor array panel according to an embodiment of the present invention includes: a substrate; a data line formed on the substrate, a source electrode connected to the data line; a drain electrode including the portion opposing the source electrode; a partition having an opening exposing the portions of the source and drain electrodes; an organic semiconductor formed in the opening; a gate insulator formed on the organic semiconductor; and a gate line crossing the data line and having a gate electrode. The semiconductor islands advantageously are completely enclosed by the partition, thereby avoiding physical and chemical damages in later process steps and simplifying manufacture.

The organic semiconductor and the gate insulator may include a soluble material, and the height of the partition may be higher than the gate insulator and the organic semiconductor.

The gate electrode may completely cover the gate insulator and the organic semiconductor, and the size of the gate electrode may be larger than the opening.

The data line and the source electrode may include different material from each other, and the source electrode and the drain electrode may include conductive oxide material. The source and the drain electrode may include ITO or IZO.

The partition may have a contact hole exposing the portion of the drain electrode, and may further include a pixel electrode connected to the drain electrode through the contact hole.

The thin film transistor array panel may further comprise a passivation layer covering the gate line.

The pixel electrode may be formed on the passivation layer.

The thin film transistor array panel may further comprise a storage electrode formed with same layer as the data line.

The drain electrode may overlap at least the portion of the storage electrode.

The thin film transistor array panel may further include an interlayer insulating layer formed between the drain electrode and the storage electrode.

The thin film transistor array panel may further include a light blocking layer formed under the organic semiconductor.

The gate insulator may include an organic material.

A method of manufacturing a thin film transistor array panel includes: forming a data signal line on a substrate; forming an interlayer insulating layer covering the data line; forming a source electrode connected to the data line and a drain electrode opposing the source electrode; forming a partition having an opening and a contact hole; dropping a semiconductor in the opening; forming a gate insulator including organic insulating material on the semiconductor; forming a gate line on the partition and the gate insulator; and forming a pixel electrode connected to the drain electrode through the contact hole.

The semiconductor and the gate insulator may be formed by inkjet printing.

The method may further include drying the organic semiconductor after dropping the organic semiconductor.

The method may further include forming a passivation layer after forming the gate line.

### BRIEF DESCRIPTION OF THE DRAWING

The foregoing objects, features and advantages of the present invention will become more apparent from a reading of the ensuing description together with the drawing, in which:

FIG. 1 is a layout view of an OTFT array panel according to an embodiment of the present invention;

FIG. 2 is a sectional view of the OTFT array panel shown in FIG. 1 taken along the line II-II;

FIGS. 3, 5, 7, 9, 11, and 13 are layout views of the OTFT array panel shown in FIGS. 1 and 2 in intermediate steps of a manufacturing method thereof according to an embodiment of the present invention;

FIG. 4 is a sectional view of the OTFT array panel shown in FIG. 3 taken along the line IV-IV;

FIG. 6 is a sectional view of the OTFT array panel shown in FIG. 5 taken along the line VI-VI;

FIG. 8 is a sectional view of the TFT array panel shown in FIG. 7 taken along the line VIII-VIII;

FIG. 10 is a sectional view of the OTFT array panel shown in FIG. 9 taken along the line X-X;

FIG. 12 is a sectional view of the OTFT array panel shown in FIG. 11 taken along the line XII-XII; and

FIG. 14 is a sectional view of the TFT array panel shown in FIG. 13 taken along the line XIV-XIV.

### DETAILED DESCRIPTION OF EMBODIMENTS

In the drawings, the thickness of layers and regions are exaggerated for clarity. Like numerals refer to like elements throughout. It will be understood that when an element such as a layer, region, or substrate is referred to as being “on” another element, it can be directly on the other element or intervening elements may also be present. In contrast, when an element is referred to as being “directly on” another element, there are no intervening elements present.

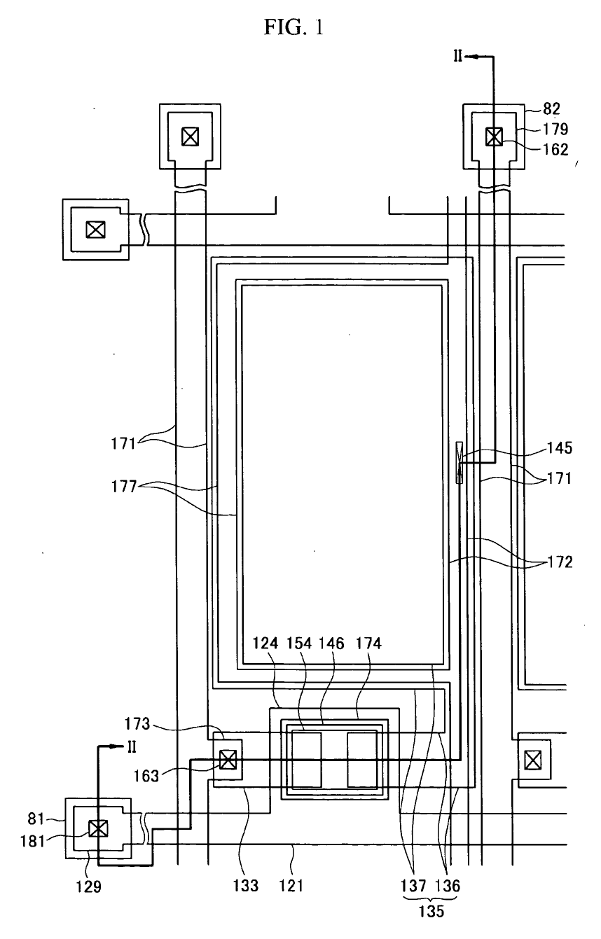

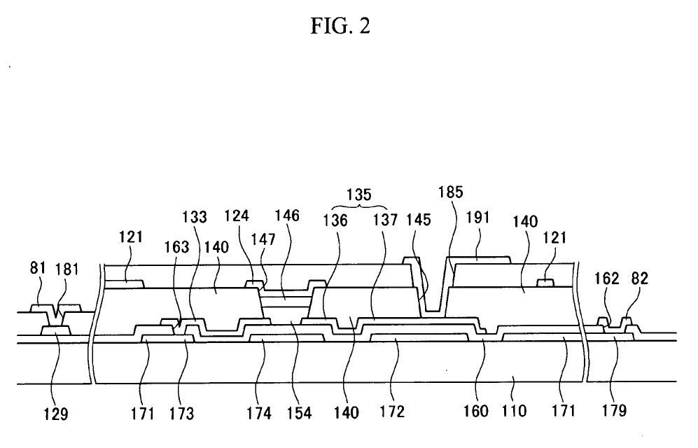

FIG. 1 is a layout view of an OTFT array panel according to an embodiment of the present invention, and FIG. 2 is a sectional view of the OTFT array panel shown in FIG. 1 taken along the line II-II.

As shown in FIGS. 1 and 2, a plurality of data lines 171, a plurality of storage electrode lines 172, and a plurality of light blocking layers 174 are formed on an insulating substrate 110 made of material such as transparent glass, silicone, or plastic.

Data lines 171 transmit data signals and extend substantially in a longitudinal direction. Each data line 171 includes a plurality of side projections 173 and an end portion 179 having a large area for contact with another layer or an external driving circuit. A data driving circuit (not shown) for generating the data signals may be mounted on a flexible printed circuit (FPC) film (not shown), which may be attached to, directly mounted, or integrated on substrate 110. Data lines 171 may extend to connect to a driving circuit that may be integrated on substrate 110.

Storage electrode lines 172 are supplied with a predetermined voltage and extend substantially parallel to data lines 171. Each of storage electrode lines 172 is disposed between, and closer to, the righthand one of two adjacent data lines 171. Each of storage electrode lines 172 includes a storage electrode 177 have an expanded, ring-shape side. However, storage electrode lines 172 may have various shapes and arrangements.

Light blocking layers 174 are separated from data lines 171 and storage electrode lines 172.

Data lines 171, storage electrode lines 131 and light blocking layers 174 are preferably made of a metal including Al or an Al alloy, Ag or a Ag alloy, Au or a Au alloy, Cu or a Cu alloy, Mo or a Mo alloy, Cr, Ta, or Ti. The conductors may have a multi-layered structure including two conductive films (not shown) having different physical characteristics. One of the two films is preferably made of a low resistivity metal including an Al-containing metal, a Ag-containing metal, and a Cu-containing metal for reducing signal delay or voltage drop in the gate lines 121 and the storage electrode lines 131. The other film is preferably made of a material such as a Mo-containing metal, Cr, Ta, or Ti, which has good physical, chemical, and electrical contact characteristics with other materials such as indium tin oxide (ITO) or indium zinc oxide (IZO). Good examples of the combination of the two films are a lower Cr film and an upper Al alloy film, and a lower Al film and an upper Mo film. However, the gate lines 121 and the storage electrode lines 131 may be made of various metals or conductors.

The lateral sides of data lines 171, storage electrode lines 172, and light blocking layers 174 are inclined relative to the surface of substrate 110, and the inclination angle thereof ranges from about 30 to 80 degrees.

An interlayer insulating layer 160 is formed on data lines 171, storage electrode lines 172, and light blocking layers 174. The interlayer insulating layer 160 may be made of an inorganic insulator. Examples of a suitable inorganic insulator include silicon nitride (SiNx) and silicon oxide (SiOx). The thickness of the interlayer insulating layer 160 may be from about 2,000 Å to about 5,000 Å.

Interlayer insulating layer 160 has a plurality of contact holes 162 exposing the end portions 179 of data lines 171 and a plurality of contact holes 163 exposing projections 173 of data lines 171.

A plurality of source electrodes 133, a plurality of drain electrodes 135 and a plurality of contact assistants 82 are formed on the interlayer insulating layer 160.

Source electrodes 133 are connected to projections 173 of data lines 171 through contact holes 163 and may have an island shape.

Each of drain electrodes 135 includes an electrode portion 136 that is disposed opposite the source electrode 133 on light blocking layer 174 and a capacitor portion 137 that overlaps at least one portion of storage electrode lines 172. The electrode portions 136 disposed opposite source electrodes 133 make a portion of a thin film transistor and the capacitor portions 137, overlapping storage electrode lines 172, serve to reinforce the voltage storage capacity of the storage capacitor.

Contact assistants 82 are connected to the end portions 179 of data lines 171 through contact holes 162. Contact assistants 82 protect the end portions 179 and enhance the adhesion between the end portions 179 and external devices.

Source electrodes 133, drain electrodes 135, and contact assistants 82 may be made of a transparent conductor such as ITO or IZO or a reflective conductor such as Ag, Al, Cr, or alloys thereof.

The difference in the work function between an organic semiconductor and the ITO layer or IZO layer may be so small that charge carriers can be effectively injected into the organic semiconductor from source electrode 133 and drain electrode 135. When the difference in the work function is small, the Schottky barrier generated between organic semiconductor 154 and electrodes 133 and 135 may easily allow the injection and transport of the charge carriers. The thicknesses of the source and the drain electrodes 133 and 135 may be from about 300 Å to about 1,000 Å.

A partition 140 is formed on source electrodes 133, drain electrode 135, and interlayer insulating layer 160. Partition 140 may be made of a photosensitive organic insulator formed by a solution process. The thickness of the insulating layer 140 may be from about 5000 Å to about 4 microns.

Partition 140 has a plurality of openings 147 exposing portions of source electrodes 133 and drain electrodes 135, and the interlayer insulating layer 160 therebetween. Partition 140 has a plurality of contact holes 145 exposing portions of drain electrodes 135.

A plurality of organic semiconductor islands 154 are formed in openings 147 of partition 140. Organic semiconductor islands 154 contact source electrodes 133 and drain electrodes 135. The height of organic semiconductor islands 154 is smaller than that of partition 140 and islands 154 are therefore completely confined within partition 140. Since the lateral surfaces of organic semiconductor islands 154 are not exposed, chemicals used in later process steps are prevented from infiltrating organic semiconductor islands 154.

The organic semiconductor islands 154 are disposed on the light blocking layer 174 for blocking the light incident to the organic semiconductor islands 154 from a back light such that the increase of the photo-leakage current may be prevented.

The organic semiconductor islands 154 may include a high molecular compound or a low molecular compound that is soluble in an aqueous solution or an organic solvent.

The organic semiconductor islands 154 may be made of or from derivatives of tetracene or pentacene with a substituent. Alternatively, the organic semiconductor islands 154 may be made of an oligothiophene including four to eight thiophenes connected at the positions 2 and 5 of thiophene rings.

The organic semiconductor islands 154 may be made of polythienylenevinylene, poly 3-hexylthiophene, polythiophene, phthalocyanine, or metallized phthalocyanine or halogenated derivatives thereof. Alternatively, the organic semiconductor islands 154 may be made of perylene tetracarboxylic dianhydride (PTCDA), naphthalene tetracarboxylic dianhydride (NTCDA), or their imide derivatives. The organic semiconductor islands 154 may also be made of perylene, coronene, or derivatives thereof with a substituent.

The thickness of the organic semiconductor islands 154 may be in the range of about 300 to 3,000 angstroms.

A plurality of gate insulators 146 are formed on the organic semiconductor islands 154. The sidewalls of the openings 147 of the partitions 140 are higher than the gate insulators 146 and the organic semiconductor islands 154 such that the partition 140 serves as a bank against the gate insulators 146 and the organic semiconductor islands 154.

The gate insulators 146 may be made of an inorganic insulator or an organic insulator. Examples of the organic insulator include a soluble high molecule compound such as a polyimide compound, a polyvinyl alcohol compound, and parylene. An example of the inorganic insulator includes silicon oxide that may have a surface treated with octadecyl-trichloro-silane (OTS).

A plurality of gate lines 121 are formed on the gate insulators 146 and the partition 140.

The gate lines 121 transmit gate signals and extend substantially in a transverse direction to intersect data lines 171 and the storage electrode lines 131. Each of the gate lines 121 includes a plurality of gate electrodes 124 projecting upward and an end portion 129 having a large area for contact with another layer or an external driving circuit. A gate driving circuit (not shown) for generating the gate signals may be mounted on an FPC film (not shown), which may be attached to substrate 110, directly mounted on substrate 110, or integrated with substrate 110. The gate lines 121 may extend to connect to a driving circuit that may be integrated on substrate 110.

The gate electrodes 124 overlap the organic semiconductor islands 154 via the gate insulators 146, and have the sufficient size to completely cover the gate insulators 146 and the organic semiconductor islands 154, and the openings 147.

The gate lines 121 may be made of a conductor material having low resistivity, such as that of data lines 171 and storage electrode lines 172.

The lateral sides of the gate lines 121 are inclined relative to a surface of substrate 110, and their inclination angles range from about 30 to about 80 degrees.

A passivation 180 is formed on the gate lines 121. The passivation layer 180 cover the end portions 129 for preventing adjacent end portions 129 from shorting to each other.

The passivation layer 180 has a plurality of contact holes 185 and 182.

The contact holes 185 expose the drain electrode 135 and are disposed on the contact holes 145 of the partitions 140, and the contact holes 181 expose the end portions 129 of the gate lines 121.

The passivation layer 180 protects the organic semiconductor islands 154 and the gate lines 121, and may be formed partially or entirely on substrate 110. Alternatively, the passivation layer 180 may be omitted.

A plurality of pixel electrodes 191 and a plurality of contact assistants 81 are formed on the passivation layer 180.

The pixel electrodes 191 are connected to the drain electrodes 135 through the contact holes 185 and 145.

The pixel electrodes 191 overlap the gate lines 121 and/or data lines 171 for maximizing the aperture ratio of the pixels.

The pixel electrodes 191 receive data voltages from the organic TFT and generate an electric field in conjunction with a common electrode (not shown) of an opposing display panel (not shown) that is supplied with a common voltage, which determines the orientations of liquid crystal molecules (not shown) in a liquid crystal layer (not shown) disposed between the two electrodes. A pixel electrode 191 and the common electrode form a capacitor referred to as a “liquid crystal capacitor,” which stores applied voltages even after the organic TFT turns off.

The contact assistants 81 are connected to the end portions 129 of the gate lines 121 through the contact holes 181, respectively. The contact assistants 81 protect the end portions 129 and enhance the adhesion between the end portions 129 and external devices.

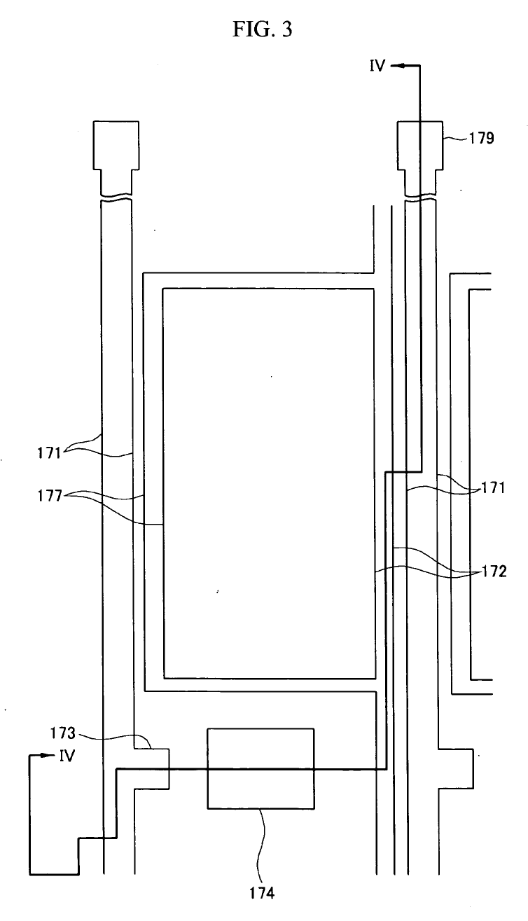

A gate electrode 124, a source electrode 133, a drain electrode 135, and an organic semiconductor island 154 form an organic TFT. The TFT has a channel formed in the organic semiconductor island 154 disposed between the source electrode 133 and the drain electrode 135. Now, a method of manufacturing the OTFT array panel shown in FIGS. 1 and 2 according to an embodiment of the present invention will be described in detail with reference to FIGS. 3-14, as well as FIGS. 1 and 2.

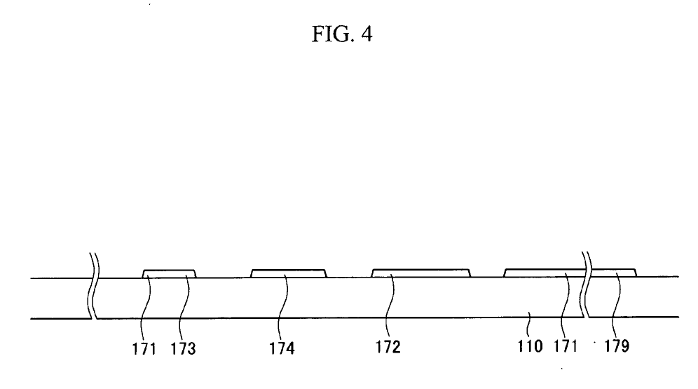

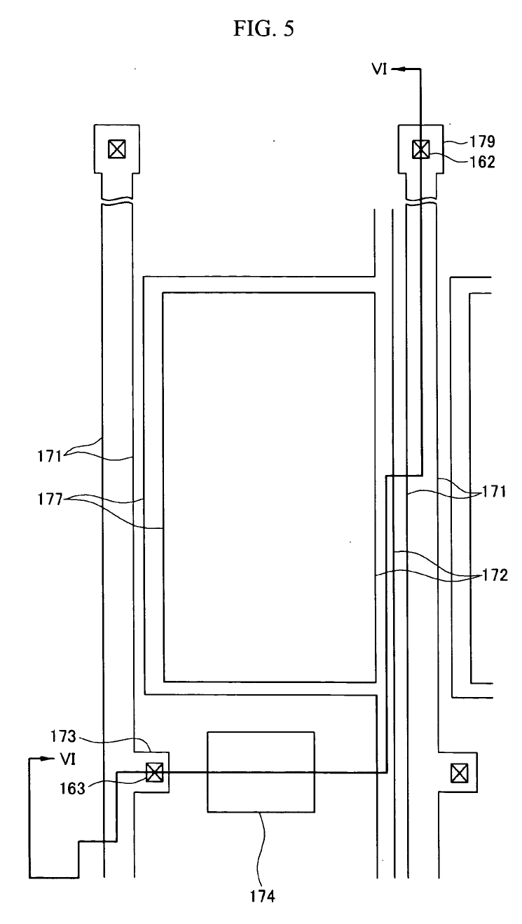

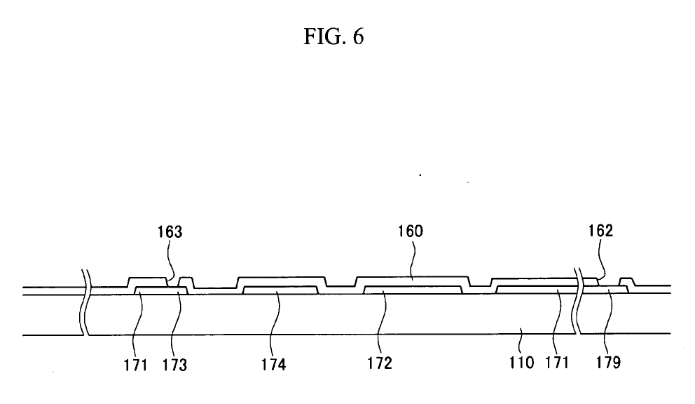

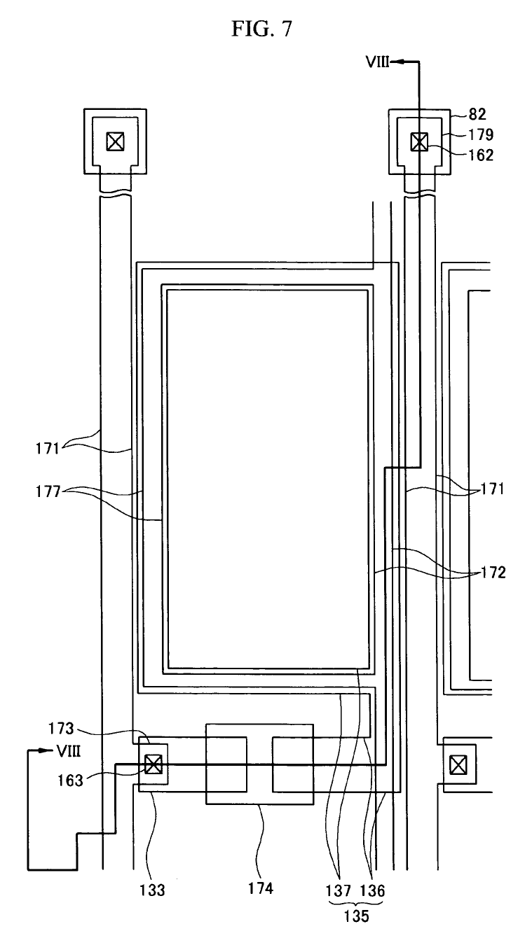

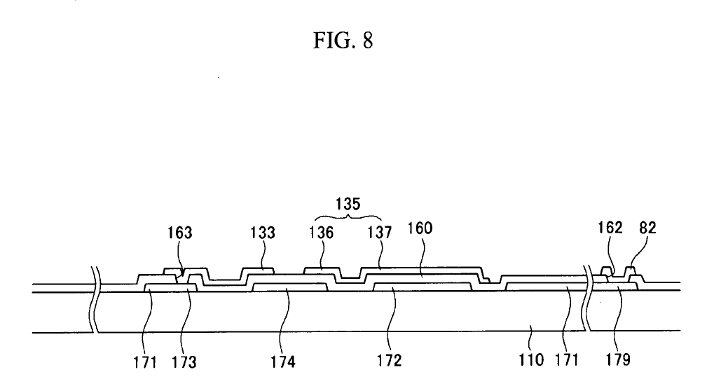

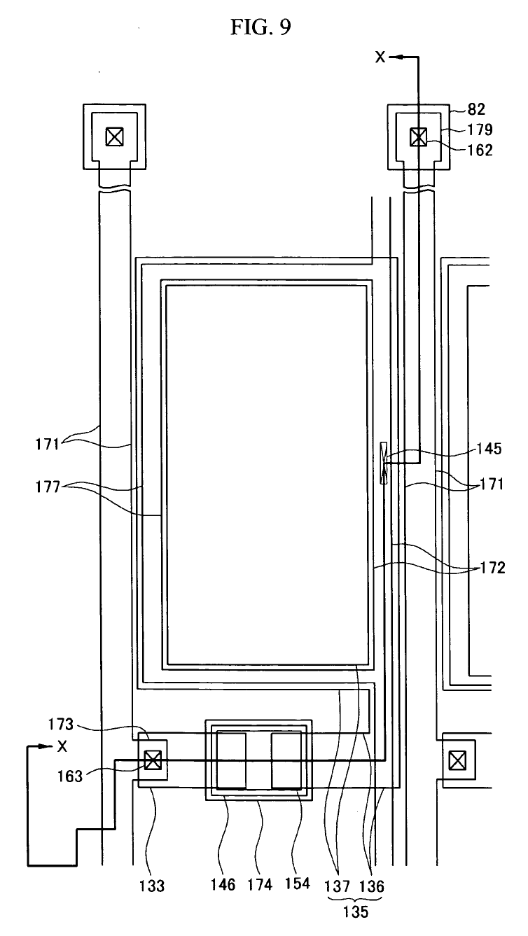

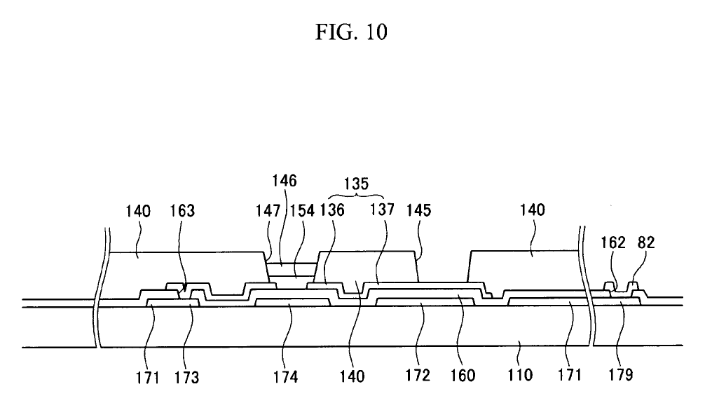

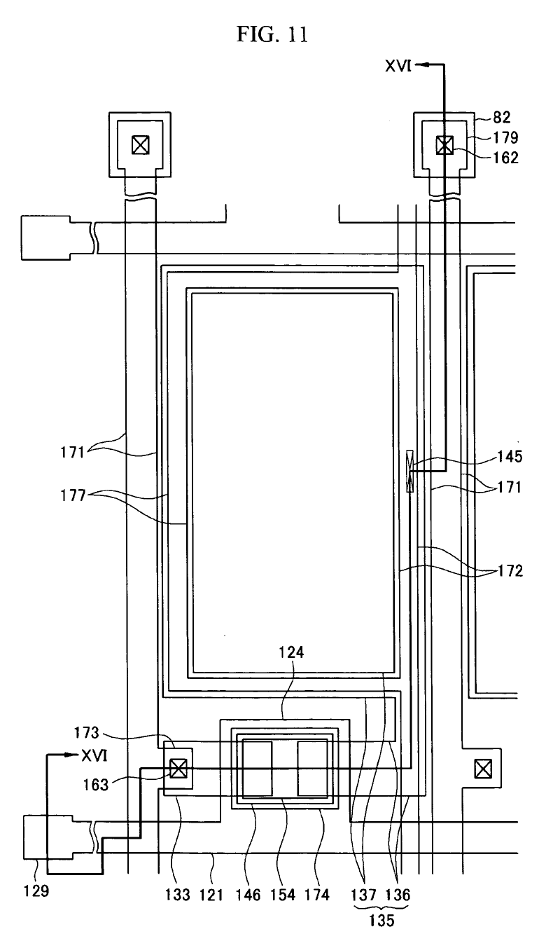

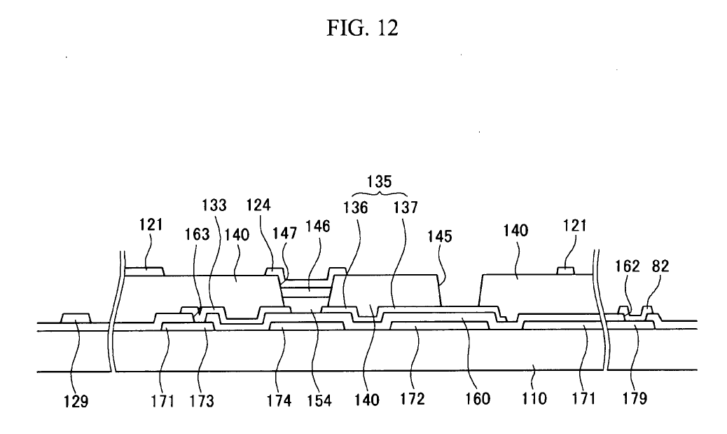

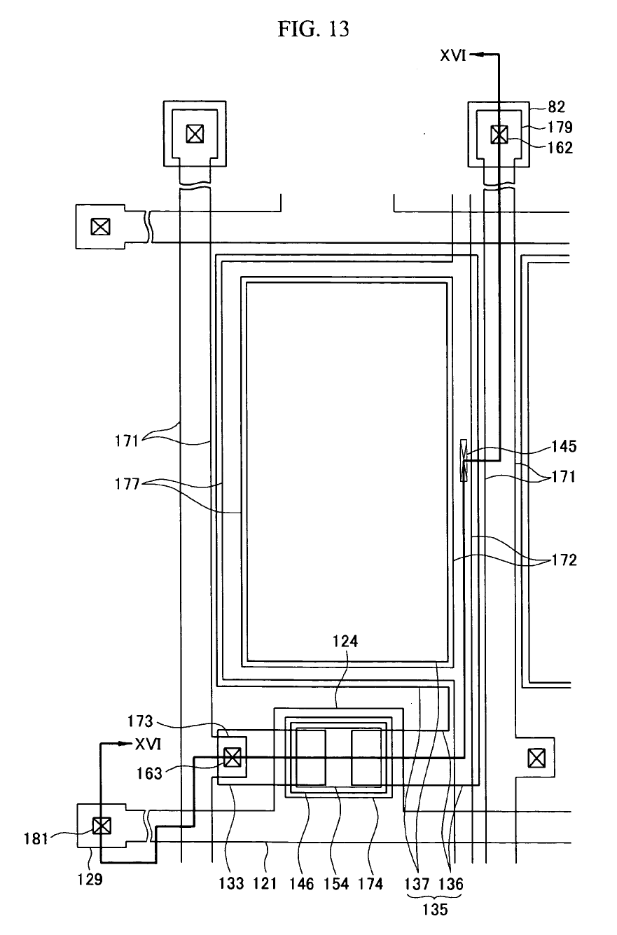

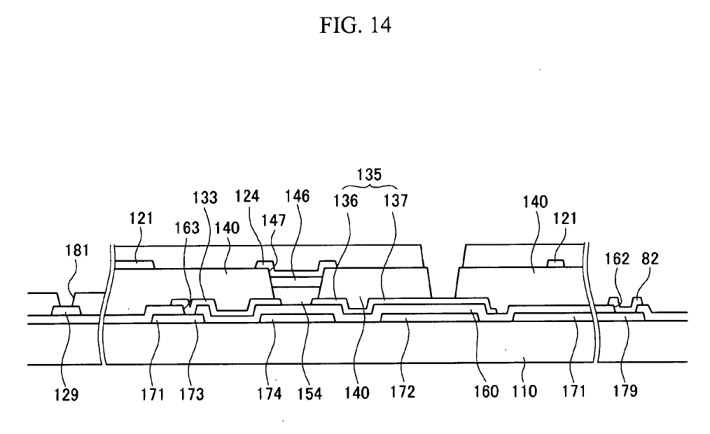

FIGS. 3, 5, 7, 9, 11, and 13 are layout views of the OTFT array panel shown in FIGS. 1 and 2 in intermediate steps of a manufacturing method thereof according to an embodiment of the present invention, FIG. 4 is a sectional view of the OTFT array panel shown in FIG. 3 taken along the line IV-IV, FIG. 6 is a sectional view of the OTFT array panel shown in FIG. 5 taken along the line VI-VI, FIG. 8 is a sectional view of the TFT array panel shown in FIG. 7 taken along the line VIII-VIII, FIG. 10 is a sectional view of the TFT array panel shown in FIG. 9 taken along the line X-X, FIG. 12 is a sectional view of the OTFT array panel shown in FIG. 11 taken along the line XII-XII, and FIG. 14 is a sectional view of the TFT array panel shown in FIG. 13 taken along the line XIV-XIV.

Referring to FIGS. 3 and 4, a conductive layer is deposited on a substrate 110 by using sputtering, etc., and is patterned by lithography and etching to form a plurality of data lines 171 including projections 173 and end portions 179, a plurality of storage electrode lines 172 including a plurality of storage electrodes 177, and a plurality of light blocking layers 174.

Referring to FIGS. 5 and 6, an interlayer insulating layer 160 including a plurality of contact holes 162 and 163 is formed by deposition and patterning. The deposition of the interlayer insulating layer 160 is performed by CVD of an inorganic material such as silicon nitride.

Referring to FIGS. 7 and 8, an ITO or IZO layer is deposited by sputtering, etc., and patterned by lithography and etching to form a plurality of source electrodes 133, a plurality of drain electrodes 135, and a plurality of contact assistants 82.

Subsequently, as shown in FIGS. 9 and 10, an organic photosensitive layer is coated on substrate 110 and is developed to form a partition 140 having a plurality of openings 147 and a plurality of contact holes 145.

A plurality of organic semiconductor islands 154 are sequentially formed in the openings 147 by inkjet printing, etc. To form the organic semiconductor islands 154, an organic semiconductor solution is dropped in the openings 147 and the solution is dried.

Successively, a plurality of gate insulators 146 are formed on the organic semiconductor islands 154 by inkjet printing, etc. The inkjet printing includes dropping and drying of a gate insulating solution.

As above-described, because the organic semiconductor islands 154 and the gate insulators 146 are successively formed, photolithography processes may be omitted. Accordingly, an additional mask may be omitted and the manufacturing processes may be simplified such that the production cost and process time may be minimized. Furthermore, because the semiconductor islands 154 are completely enclosed by the partition 140, physical and chemical damages in later process steps may be minimized.

Subsequently, as shown in FIGS. 11 and 12, a conductive layer is deposited and patterned by lithography and etching to form a plurality of gate lines 121 including gate electrodes 124 and end portions 129. Here, gate electrodes 124 are large enough in size to cover openings 147.

As shown in FIGS. 13 and 14, a passivation layer is formed and etched with a photolithography process to form a plurality of contact holes 181 and 185.

Finally, as shown in FIGS. 1 and 2, a plurality of pixel electrodes 191 and a plurality of contact assistants 81 that are respectively connected to the drain electrodes 135 and end portions 129 of gate lines 121 are formed thereon.

As above described, the gate insulators and the semiconductors are successively and easily formed without an additional mask and are enclosed by the partition such that the influences by later process steps may be minimized and the manufacturing process may be simplified. Also, the source and drain electrodes include material having good contact characteristics with the organic semiconductors, and accordingly the characteristics of organic TFT may be improved.

Although preferred embodiments of the present invention have been described in detail hereinabove, it should be clearly understood that many variations and/or modifications of the concepts herein will be apparent to those skilled in the art and may be made without, however, departing from the spirit and scope of the invention.

What is claimed is:

1. A thin film transistor array panel comprising:
a substrate;
a data line formed on the substrate;
a source electrode connected to the data line;
a drain electrode including a portion opposing the source electrode;
a partition having an opening exposing portions of the source and drain electrodes;
an organic semiconductor formed in the opening;
a gate insulator formed on the organic semiconductor; and
a gate line crossing the data line and having a gate electrode.

2. The thin film transistor array panel of claim 1, wherein the organic semiconductor and the gate insulator include a soluble material.

3. The thin film transistor array panel of claim 1, wherein the height of the partition is higher than the gate insulator and the organic semiconductor.

4. The thin film transistor array panel of claim 1, wherein the gate electrode completely covers the gate insulator and the organic semiconductor.

5. The thin film transistor array panel of claim 1, wherein the size of the gate electrode is larger than the opening.

6. The thin film transistor array panel of claim 1, wherein the data line and the source electrode include different materials from each other.

7. The thin film transistor array panel of claim 1, wherein the source electrode and the drain electrode include a conductive oxide material.

8. The thin film transistor array panel of claim 7, wherein the source and the drain electrode include ITO or IZO.

9. The thin film transistor array panel of claim 1, wherein the partition has a contact hole exposing a portion of the drain electrode, and further comprising a pixel electrode connected to the drain electrode through the contact hole.

10. The thin film transistor array panel of claim 9, further comprising a passivation layer covering the gate line.

11. The thin film transistor array panel of claim 10, wherein the pixel electrode is formed on the passivation layer.

12. The thin film transistor array panel of claim 1, further comprising a storage electrode formed on the same layer as the data line.

13. The thin film transistor array panel of claim 12, wherein the drain electrode overlaps at least a portion of the storage electrode.

14. The thin film transistor array panel of claim 13, further comprising an interlayer insulating layer formed between the drain electrode and the storage electrode.

15. The thin film transistor array panel of claim 1, further comprising a light blocking layer formed under the organic semiconductor.

16. The thin film transistor array panel of claim 1, wherein the gate insulator includes an organic material.

17. A method of manufacturing a thin film transistor array panel, the method comprising:
forming a data signal line on a substrate;
forming an interlayer insulating layer covering the data line;
forming a source electrode connected to the data line and a drain electrode opposing the source electrode;
forming a partition having an opening and a contact hole;
dropping a semiconductor in the opening;
forming a gate insulator including organic insulating material on the semiconductor;
forming a gate line on the partition and the gate insulator; and
forming a pixel electrode connected to the drain electrode through the contact hole.

18. The method of claim 17, wherein the semiconductor and the gate insulator are formed by inkjet printing.

19. The method of claim 18, further comprising drying the organic semiconductor after dropping the organic semiconductor.

20. The method of claim 17, further comprising forming a passivation layer after forming the gate line.
